(19) United States
(12) Patent Application Publication
(10) Pub. No.: US 2017/0154863 A1
(43) Pub. Date: Jun. 1, 2017

(54) COPPER BONDING WIRE WITH ANGSTROM (Å) THICK SURFACE OXIDE LAYER

(71) Applicant: Heraeus Deutschland GmbH & Co. KG, Hanau (DE)

(72) Inventors: Murali SARANGAPANI, Singapore (SG); Xi ZHANG, Singapore (SG); Ping Ha YEUNG, Singapore (SG); Eugen MILKE, Nidderau (DE)

(73) Assignees: Heraeus Deutschland GmbH & Co. KG, Hanau (DE); Heraeus Deutschland GmbH & Co. KG, Hanau (DE)

(21) Appl. No.: 15/320,492

(22) PCT Filed: Jun. 17, 2015
(86) PCT No.: PCT/EP2015/063508

§ 371 Date: Dec. 20, 2016

(30) Foreign Application Priority Data
Jun. 23, 2014 (SG) 10201403532Q

(51) Int. Cl. H01L 23/00; C22F 1/08; B21C 1/02; C22C 9/00

(52) U.S. Cl. CPC H01L 24/45; H01L 24/43; C22C 9/00; C22F 1/08; B21C 1/02; H01L 2224/45015; H01L 2224/45147; H01L 2224/45565; H01L 2924/20751; H01L 2924/20752; H01L 2924/20753; H01L 2924/20754; H01L 2924/20755; H01L 2924/20756; H01L 2924/20757; H01L 2924/20758; H01L 2924/01047; H01L 2924/01046; H01L 2224/43848; H01L 2224/43985; H01L 2224/4321; H01L 2224/45686; H01L 2924/0541

(57) ABSTRACT

A copper wire having a diameter of 10 to 80 μm is provided. The copper wire bulk material is ≧99.99 wt.-% pure copper or a copper alloy consisting of 10 to 1000 wt.-ppm of silver and/or of 0.1 to 3 wt.-% of palladium with copper as the remainder to make up 100 wt.-%, and the copper wire has a 0.5 to <6 nm thin circumferential surface layer of copper oxide.

### CROSS-REFERENCE TO RELATED APPLICATIONS

This application is a Section 371 of International Application No. PCT/EP2015/063508, filed Jun. 17, 2015, which was published in the English language on Dec. 30, 2915 under International Publication No. WO 2015/197432 A1 and the disclosure of which is incorporated herein by reference.

### BACKGROUND OF THE INVENTION

The use of bonding wires in electronics and microelectronics applications is well-known state of the art. While bonding wires were originally made from gold, nowadays less expensive materials such as copper are used. While copper wire provides very good electric and thermal conductivity, bonding of copper wire has its challenges. Moreover, copper wires are susceptible to oxidation of the wire.

There have been various approaches to prevent copper bonding wires from surface oxidation. Examples include coating the copper wire with a coating of an oxidation-resistant noble metal, a glass coating or a polymer coating.

Uncoated copper wires for wire bonding applications typically have a surface layer of copper oxide, the layer thickness whereof typically lying in the range of, for example, 6 to 20 nm.

### BRIEF SUMMARY OF THE INVENTION

The invention is related to a copper wire having an only 0.5 to <6 nm thin circumferential surface layer of copper oxide. The term “copper oxide” as used herein shall mean CuO and/or Cu₂O.

As a result of extensive R&D effort, a copper wire has been developed having a diameter of 10 to 80 μm, preferably 15 to 50 μm, and a 0.5 to <6 nm, preferably 0.5 to 4 nm, in particular 0.5 to 3.5 nm thin circumferential surface layer of copper oxide. The copper wire bulk material is either ≧99.99 wt.-% (weight-%) pure copper or a copper alloy consisting of 10 to 1000 wt.-ppm (weight-ppm), preferably 100 to 300 wt.-ppm, in particular 200 to 250 wt.-ppm of silver and/or of 0.1 to 3 wt.-%, preferably 0.5 to 2 wt.-%, in particular 1.2 to 1.3 wt.-% of palladium with copper as the remainder to make up 100 wt.-%.

### DETAILED DESCRIPTION OF THE INVENTION

The term “copper wire” is used herein. To avoid misunderstandings, it shall mean the copper wire in any form, i.e., as unprocessed copper wire and as processed, i.e., ball- or wedge-bonded copper wire.

The term “0.5 to <6 nm thin circumferential surface layer of copper oxide” as used shall mean that the 0.5 to <6 nm thin circumferential surface layer of copper oxide is copper oxide or that it comprises copper oxide. In other words, the 0.5 to <6 nm thin circumferential surface layer of copper oxide may consist of copper oxide or it may comprise copper oxide in a concentration lying in the range of, for example, 50 to 100 wt.-%. In an embodiment, it exhibits a concentration gradient of copper oxide over the depth of the 0.5 to <6 nm in perpendicular direction from the outer wire surface to the center of the wire. Such copper oxide concentration may be high at the outer wire surface, for example, 90 to 100 wt.-% of copper oxide, and it diminishes rapidly down to 0 wt.-% over this depth.

In the following, the “copper alloy consisting of 10 to 1000 wt.-ppm of silver and/or of 0.1 to 3 wt.-% of palladium with copper as the remainder to make up 100 wt.-%” is also called “copper alloy” for short.

The phrase “copper as the remainder to make up 100 wt.-%” as used herein shall mean that copper is the main component in the copper alloy. To avoid misunderstandings, this shall not be understood to exclude other elements which are not expressly named and which, due to prevailing technical conditions, may have found their way into the copper alloy, for example, as a consequence of an unintentional but inevitable incorporation during manufacture. In other words, such other elements may be present in the alloy as inevitable impurities, however only in a very minor total amount of, for example, >0 to 100 wt.-ppm. In any case, such inevitable impurities are not deliberately added or introduced into the copper alloy forming composition. Insofar, the phrase “copper as the remainder to make up 100 wt.-%” means that the wt.-% proportion which is missing to make up 100 wt.-% of the copper alloy consists of copper plus said inevitable impurities, if the latter are present.

The copper alloy can be prepared by conventional processes known to the person skilled in the art of metal alloys, for example, by melting together the copper and the silver and/or palladium in the desired ratio. In doing so, it is possible to make use of conventional copper-silver or copper-palladium master alloys. The melting process can, for example, be performed making use of an induction furnace and it is expedient to work under vacuum or under an inert gas atmosphere. The materials used can have a purity grade of, for example, 99.99 wt.-% and above. The copper alloy melt is typically cast in a mold of room temperature in which it cools down and solidifies.

The nature and the thickness of a copper or copper alloy wire's surface layer of copper oxide can be determined or characterized by time of flight-secondary ion mass spectrometry (ToF-SIMS) with use of bismuth ion to analyze the molecules in positive polarity).

The thickness of a copper or copper alloy wire's surface layer of copper oxide can also be measured by the following equivalent methods:

Depth profiling using Ar ion sputtering in steps for period of time until 100% copper (Cu) is observed. This method is well-known to the skilled person and does not require further explanation.

X-ray photoelectron spectroscopy (XPS) by depth profiling using standard practice. This method is well-known to the skilled person and does not require further explanation.

Sequential electrochemical reduction analysis (SERA). For SERA the device Surface-Scan QC200 from ECI Technology can be used. ECI Technology discloses details on its website http://wtww.ecitechnokol.com/sites/defaulfikil/dwnloadsVeci-surfacesan-qc200.pdfcan, according to which SERA can be used as a quality control tool to define the tolerances of copper wire surface oxide layer thickness. Basically, Faraday's principle is used to measure the copper oxide thickness by dissolving the copper oxide layer using borate electrolyte of about 8.5 pH. SERA is capable of analyzing Cu₂O, CuO and Cu₂S on the copper wire surface similar to bulk copper. SERA records the reaction potential of Cu₂O, CuO and Cu₂S versus time. The reaction potential in the range of −0.4 to −0.6 V, −0.8 to −0.9 V, −0.9 to −1.0 V, and −1.1 to −1.2 V corresponds to the reduction of Cu₂O, CuO, Cu₂S and H₂ evolution, respectively. The time of reduction of surface oxide/sulfide is proportionate to the presence of layer thickness (T), calculated as per Faraday's equation:

$$T = \frac{M * I * t * {10}^{8}}{n * F * S * d}$$

where I is current in ampere, t is reduction time measured in seconds, M is molecular weight in g, F is Faraday's constant (96498 coulombs), n is number of electrons, S is surface area of immersed copper section in cm² and d is density of film in g/cm³.

The SERA method is the preferred method for measuring the layer thickness of a copper or copper alloy wire's surface layer of copper oxide.

In a particular embodiment, the copper wire of the invention exhibits free carbon (elemental carbon) at its surface i.e., on top of the surface layer of copper oxide and/or as a concentration gradient of free carbon over a depth of, for example, 0.6 to 5 nm in perpendicular direction from the outer wire surface to the center of the wire. Such free carbon concentration may be high at the outer wire surface, for example, 90 to <100 wt.-% of free carbon and diminishes rapidly down to 0 wt.-% over the depth. The concentration gradient of free carbon may overlap with the afore mentioned concentration gradient of copper oxide.

The depth of the free carbon gradient can be determined or characterized by ToF-SIMS (with bismuth ion to analyze the molecules in positive polarity) or by XPS by depth profiling using standard practice.

The invention is also related to a process for the manufacture of the copper wire of the invention. The copper wire of the invention can be made by a process comprising the steps:
(a) providing a copper precursor of ≧99.99 wt.-% pure copper or of the copper alloy,
(b) drawing the precursor until a final diameter of 10 to 80 μm, preferably 15 to 50 μm, of the wire is reached;
(c) annealing the drawn wire at an object temperature (peak temperature) of 580 to 750° C. for 0.2 to 0.4 seconds in a 90 to 96 vol.-% (volume-%) inert gas:4 to 10 to vol.-% hydrogen atmosphere, and
(d) quenching the annealed wire in water,
wherein the vol.-% total of the atmosphere is 100 vol.-%.

In step (a) of the process of the invention, a copper precursor of ≧99.99 wt.-% pure copper or of the copper alloy is provided.

Typically, such a copper precursor is in the form of a rod having a diameter of, for example, 2 to 25 mm and a length of, for example, 5 to 100 m. Such a rod can be made analogously or in accordance with the afore disclosed process for the preparation of the copper alloy, i.e., by casting the copper or copper alloy melt in an appropriate mold of room temperature, followed by cooling and solidifying.

In step (b) of the process of the invention, the copper precursor is drawn in several steps until a final diameter of 10 to 80 μm, preferably 15 to 50 μm, of the wire is reached. Such a wire drawing process is well known to the person skilled in the art. Conventional tungsten and diamond drawing dies may be employed and conventional drawing lubricants may be employed to support the drawing. Typically, the copper wire obtained after completion of step (b) has a circumferential surface layer of copper oxide with a layer thickness in the range of, for example, 6 to 20 nm.

In step (c) of the process of the invention, the drawn wire is annealed (finally annealed, strand annealed) at an object temperature of 570 to 750° C. for 0.2 to 0.4 seconds in a 90 to 96 vol.-% inert gas:4 to 10 vol.-% hydrogen atmosphere, wherein the vol.-% total 100 vol.-%.

In case of a ≧99.99 wt.-% pure copper wire, it is preferred to choose an object temperature of 570 to 630° C., while in case of a copper alloy wire, the preferred object temperature is in the range of 620 to 750° C., in particular 650 to 710° C.

A 95 vol.-% inert gas:5 vol.-% hydrogen atmosphere is a preferred atmosphere. The inert gas may be nitrogen and/or argon; typically, it is nitrogen.

The annealing is typically performed by pulling the wire through a conventional annealing oven, typically in the form of a cylindrical tube of a given length and with a defined temperature profile at a given speed. In doing so, the annealing time/object temperature parameters can be defined and set. The annealing oven is purged with the 90 to 96 vol.-% inert gas:4 to 10 vol.-% hydrogen mixture. Purging is preferably performed at a gas exchange rate (=gas flow rate [liter/min]:inner oven volume [liter]) lying in the range of 43 to 125 min⁻¹, more preferably 43 to 75 min⁻¹, most preferably 50 to 63 min⁻¹.

In step (d) of the process of the invention, the annealed wire is quenched in water which, in an embodiment, may contain a surfactant, for example, 0.01 to I volume-% of surfactant. Quenching in water means immediately or rapidly, i.e., within 0.2 to 0.4 seconds, cooling the annealed wire from the object temperature it received in step (c) down to room temperature.

It has been found that the copper wire of the invention which is distinguished by its only 0.5 to <6 nm thin circumferential surface layer of copper oxide is well suited for use as a bonding wire in wire bonding applications, while the copper wire of the invention in its afore mentioned particular embodiment is particularly well suited for such use.

The wire bonding technique is well known to the skilled person. In the course of wire bonding, it is typical that a ball bond (1^{st} bond) and a stitch bond (2^{nd} bond, wedge bond) are formed. During bond forming, a certain force (typically measured in grams) is applied, supported by application of ultrasonic energy (typically measured in mA). The mathematical product of the difference between the upper and the lower limits of the applied force and the difference between the upper and the lower limits of the applied ultrasonic energy in a wire bonding process defines the wire bonding process window:

(Upper limit of applied force−Lower limit of applied force)−(Upper limit of ultrasonic energy applied−Lower limit of ultrasonic energy applied)=Wire bonding process window.

The wire bonding process window defines the area of force/ultrasonic energy combinations which allow formation of a wire bond that meets specifications, i.e., which passes the conventional tests such as conventional pull tests, ball shear test, and ball pull test, to name only a few.

For industrial applications, it is desirable to have a wide wire bonding process window for reasons of wire bonding process robustness. The copper wire of the invention exhibits a considerably wide wire bonding process window for a copper bonding wire. For example, a copper wire of the invention 20 μm in diameter exhibits a wire bonding process window in the range of, for example, 60 to 130 mA·g for ball bonding and, for example, 2500 to 6000 mA·g for stitch bonding.

The wire bonding results are the same irrespective of the wire diameter and wire types, i.e. ≧99.99 wt.-% pure copper or copper alloy. It is further believed that the 0.5 to <6 nm thin circumferential surface layer of copper oxide is key for the wide wire bonding process window of the copper wire of the invention. It can be said that <6 nm of circumferential surface layer of copper oxide is a level to attain good ball and stitch bonding.

It is believed that the unique combination of the process parameters prevailing during steps (c) and (d) of the process of the invention is essential for obtaining the copper wire of the invention with its considerably wide wire bonding process window. A preferred combination of these process parameters is: object temperature of 570 to 750° C. (570 to 630° C. in case of ≧99.99 wt.-% pure copper; 620 to 750° C. or more preferred 650 to 710° C. in case of copper alloy) for 0.2 to 0.4 seconds, use of a 95 vol.-% inert gas:5 vol.-% hydrogen gas mixture as purging gas at a gas exchange rate in the range of 43 to 125 min⁻¹, more preferably 43 to 75 min⁻¹, and rapid cool down to room temperature within 0.2 to 0.4 seconds. An optimum was found with the following combination of process parameters: object temperature of 570 to 750° C. (570 to 630° C. in case of ≧99.99 wt.-% pure copper; 620 to 750° C. or more preferred 650 to 710° C. in case of copper alloy) for 0.2 to 0.4 seconds, use of a 95 vol.-% inert gas:5 vol.-% hydrogen gas mixture as purging gas at a gas exchange rate in the range of 50 to 63 min⁻¹, and rapid cool down to room temperature within 0.2 to 0.4 seconds.

After completion of step (d), the copper wire of the invention is finished. In order to fully benefit from its wide wire bonding process window, it is expedient to either use it immediately for wire bonding applications, i.e., without delay, for example, within no longer than 7 days after completion of step (d). Alternatively, in order to maintain the copper wire's wide wire bonding process window property and in order to prevent it from oxidative or other chemical attack, the finished copper wire is typically spooled and vacuum sealed immediately after completion of step (d), i.e., without delay, for example, within <I to 5 hours after completion of step (d) and then stored for further use as bonding wire. Storage in vacuum sealed condition should not exceed 6 months. After opening the vacuum seal, the copper wire should be used for wire bonding within no longer than 7 days.

It is preferred that all process steps (a) to (d) as well as spooling and vacuum sealing are carried out under clean room conditions (US FED STD 209E cleanroom standards, 1 k standard).

The following non-limiting examples illustrate the invention.

### EXAMPLES

General Procedure:

A copper rod of 99.99 wt.-% purity was melted in a vacuum induction furnace and continuously casted into rods of 8 mm in diameter. In further examples small amounts of Cu-10 wt.-% Ag or Cu-15 wt.-% Pd master alloy were added to the melt to cast Cu—Ag and Cu—Pd alloys, respectively with the following composition:

Composition
(wt.-ppm)

| | Ag | Pd |
|---|---|---|
| 99.99 wt.-% pure | 12 | 1.2 |
| copper | | |
| Cu—Ag alloy | 225 | 0.9 |
| Cu—Pd alloy | 10 | 12490 |

Further, these continuous cast rods were cold wire drawn at room temperature (25° C.). A tungsten carbide die was used to draw heavy wire and a diamond die was used for further reduction. Drawing was performed in four steps at different drawing speeds: heavy wire drawing from 8 mm to 4 mm at 0.5 m/s and 4 mm to 0.8 mm at 1 m/s, intermediate wire drawing from 0.8 mm to 0.16 mm at 4 m/s, and fine wire drawing from 0.16 mm to 0.02 mm at 6 m/s. Drawing was supported by using of a water-based lubricant. The die reduction ratio was 14% for thick wires (diameter of >200 μm) and 8% for fine wires (diameter of <200 μm).

The alloyed Cu—Ag and Cu—Pd wires were intermediate annealed at a diameter of 45 μm at 400° C. and 600° C., respectively. The 99.99 wt.-% pure copper wire was not intermediate annealed.

The drawn wires had a final diameter of 20 μm and exhibited a circumferential copper oxide layer having a layer thickness of 12 nm (average).

The wires were finally strand annealed by running them through a conventional annealing oven and using conventional equipment (including reels, spools, pulleys). Annealing time was 0.3 s. The strand annealing temperature was 600° C. (pure copper), 630° C. (Cu—Ag alloy) and 700° C. (Cu—Pd alloy). The oven was purged with forming gas (N₂:H₂, 95:5) at a gas exchange rate as shown in Table 2.

Immediately after leaving the oven, i.e., within 0.3 s, the hot wire was quenched in deionized water. Finally, the annealed wire was spooled on a clean anodized (plated) aluminum spool of 50 mm in diameter, vacuum packed and stored.

A typical electro-chemical record measured using SERA of the annealed 99.99 wt.-% pure copper wire showed a reaction potential in the range of −0.4 to −0.6V, indicating the existence of a thin Cu₂O layer on the wire surface. CuO and Cu₂S were absent. From the record, Cu₂O thickness was calculated to be in the range between 1.7 and 3 nm.

Moreover, ToF-SIMS and XPS revealed free carbon (no evidence of carbide) on the wire surface. ToF-SIMS depth profiling identified the presence of strong carbon earlier to I nm deep and further down to zero at a depth of about 5 nm. ToF-SIMS depth profile demonstrated that free carbon was likely to be present on the top of the copper oxide layer, because the free carbon peak was observed to be strong until 1 nm and a strong peak of oxygen and Cu₂ was found after 1 nm.

The wires were tested by ball bonding (1^{st} bond) to Al bond pads and stitch bonding (2^{nd} bond) to silver lead fingers. The free air ball (FAB) was formed under reactive environment by purging with forming gas (N₂:H₂; 95:5) and it was bonded to Al bond pads attaining strong ball bonding greater than 0.01 g/μm² (6.5 g/mil²) and ball pull greater than 8 g.

The following Table 2 shows wire bonding process window results:

TABLE 2
Ball and stitch bond (1^{st} and 2^{nd} bond) process window

| | | | | | | | Cu—Ag | Cu—Pd |
|---|---|---|---|---|---|---|---|---|
| | 99.99 wt-% pure copper | | | | | | alloy | alloy |
| Wire sample | 1 | 2 | 3 | 4 | 5 | 6 | 7 | 8 |

Ball bond process window (1^{st} bond)

| | | | | | | | | |
|---|---|---|---|---|---|---|---|---|
| Purging gas | 12.5 | 25 | 37.5 | 50 | 62.5 | 71.2 | 50 | 50 |
| exchange rate | | | | | | | | |
| (min⁻¹) during | | | | | | | | |
| wire strand | | | | | | | | |
| annealing | | | | | | | | |
| FAB | N.A. | N.A. | N.A. | ++++ | ++ | ++ | ++++ | ++++ |
| USG (mA) | N.A. | N.A. | N.A. | 80-94 | 80.90 | 80-90 | 77-94 | 82-94 |
| Force (g) | N.A. | N.A. | N.A. | 20-27 | 20-27 | 20-27 | 20-27 | 20-27 |
| Window Area | 0 | 0 | 0 | 98 | 70 | 70 | 119 | 84 |
| (mA · g) | | | | | | | | |

Stitch bond process window (2^{nd} bond)

| | | | | | | | | |
|---|---|---|---|---|---|---|---|---|
| USG, mA | N.A. | N.A. | N.A. | 85-160 | 90-140 | 90-140 | 75-160 | 90-160 |
| Force (g) | N.A. | N.A. | N.A. | 75-140 | 75-140 | 75-140 | 70-140 | 75-140 |
| Window Area | 0 | 0 | 0 | 4875 | 3250 | 3250 | 5950 | 4550 |
| (mA · g) | | | | | | | | |

USG = ultrasonic energy
++++ Excellent,
+++ Very good,
++ Good,
+ Fair

All of the inventive wire samples 4 to 8 resulted in a process window which was well suited for industrial application. In particular, inventive wire sample 7 showed values of 119 mA g and 5950 mA·g for 1^{st} and 2^{nd} bond, respectively.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-17. (canceled)

18. A copper wire having a diameter of 10 to 80 μm and comprising a copper wire bulk material and a 0.5 to <6 nm thin circumferential surface layer of copper oxide, wherein the copper wire bulk material is ≧99.99 wt.-% pure copper or a copper alloy consisting of 10 to 1000 wt.-ppm silver and/or 0.1 to 3 wt.-% palladium and balance copper to 100 wt.-%.

19. The copper wire of claim 18, wherein the wire exhibits a concentration gradient of free carbon over a depth of 0.6 to 5 nm in a perpendicular direction from an outer wire surface.

20. The copper wire of claim 18, wherein the wire is obtained by a process comprising the steps of:
(a) providing a copper precursor containing ≧99.99 wt.-% pure copper or the copper alloy,
(b) drawing the precursor to reach a final wire diameter of 10 to 80 μm;
(c) annealing the drawn wire at an object temperature of 570 to 750° C. for 0.2 to 0.4 seconds in an atmosphere containing 90 to 96 vol.-% inert gas:4 to 10 to vol.-% hydrogen, and
(d) quenching the annealed wire in water,
wherein the vol.-% total of the atmosphere is 100 vol.-%.

21. The copper wire of claim 20, wherein the copper wire bulk material contains ≧99.99 wt.-% pure copper and the object temperature is 570 to 630° C.

22. The copper wire of claim 20, wherein the copper wire bulk material is the copper alloy and the object temperature is in the range of 620 to 750° C.

23. The copper wire of claim 20, wherein the volume ratio of inert gas:hydrogen is 95:5.

24. The copper wire of claim 20, wherein the inert gas is nitrogen and/or argon.

25. The copper wire of claim 20, wherein the annealing is performed by pulling the wire through an annealing oven which is purged with the inert gas/hydrogen mixture at a gas exchange rate in the range of 43 to 125 min⁻¹.

26. The copper wire of claim 25, wherein the gas exchange rate is in the range of 43 to 75 min⁻¹.

27. A process for the production of the copper wire of claim 18 comprising the steps of:
(a) providing a copper precursor containing ≧99.99 wt.-% pure copper or the copper alloy,
(b) drawing the precursor to reach a final wire diameter of 10 to 80 μm;
(c) annealing the drawn wire at an object temperature of 570 to 750° C. for 0.2 to 0.4 seconds in an atmosphere containing 90 to 96 vol.-% inert gas:4 to 10 to vol.-% hydrogen, and
(d) quenching the annealed wire in water,
wherein the vol.-% total of the atmosphere is 100 vol.-%.

28. The process of claim 27, wherein the copper wire bulk material contains ≧99.99 wt.-% pure copper and the object temperature is 570 to 630° C.

29. The process of claim 27, wherein the copper wire bulk material is the copper alloy and the object temperature is in the range of 620 to 750° C.

30. The process of claim 27, wherein the volume ratio of inert gas:hydrogen is 95:5.

31. The process of claim 27, wherein the inert gas is nitrogen and/or argon.

32. The process of claim 27, wherein the annealing is performed by pulling the wire through an annealing oven which is purged with the inert gas/hydrogen mixture at a gas exchange rate in the range of 43 to 125 min⁻¹.

33. The process of claim 32, wherein the gas exchange rate is in the range of 43 to 75 min⁻¹.

34. The copper wire of claim 18, wherein the wire is used for a wire bonding application.
